(19) United States
(12) Patent Application Publication
(10) Pub. No.: US 2011/0073159 A1
(43) Pub. Date: Mar. 31, 2011

(54) Heat Dissipating Device and Module Using Same

(76) Inventors: Yu-Nung SHEN, Taipei City (TW); Tsung-Chi Wang, Taipei City (TW)

(21) Appl. No.: 12/890,912

(22) Filed: Sep. 27, 2010

(30) Foreign Application Priority Data
Sep. 28, 2009 (TW) 098132652

(51) Int. Cl. F21V 7/00; H05K 7/20; F21V 29/00; F28D 15/00; F28F 13/12; H01L 31/052

(52) U.S. Cl. 136/246; 361/697; 362/382; 362/235; 165/104.31; 165/104.33; 165/104.34; 165/104.26

(57) ABSTRACT

The present invention relates to a heat dissipating device adapted for use in combination with a module provided with a mounting board. The heat dissipating device has a metallic heat-dissipating member including a body and a number of spaced-apart heat dissipating fins extending upwardly from the upper surface of the body. The body is formed at its central portion with a through hole adapted for receiving a protrusion block protruding from a back surface of the mounting board of the module opposite to a mounting surface on which electrical devices are mounted. The heat dissipating device further includes a pump unit, a fluid conduit and a fan unit disposed on the heat dissipating fins.

### BACKGROUND OF THE INVENTION

1. Field of the Invention

The present invention relates to a heat dissipating device and a module using the same.

2. Description of the Prior Art

It is a global trend of using light-emitting diodes (LEDs) in replacement of traditional light sources in illumination apparatuses. The extensive use of LEDs as a light source in illumination apparatuses, however, has not prevailed to date due to lack of methods and apparatuses that are capable of effectively reducing the working temperature of LEDs to thereby suppress the decay in light emission therefrom and enhance the brightness thereof.

In view of the above, the inventors have devised a heat dissipating device, as well as a module using the same, to fulfill the need in this respect.

### SUMMARY OF THE INVENTION

Accordingly, an object of the invention is to provide a heat dissipating device and a module using the same.

In order to achieve this object, a heat dissipating device adapted for use in combination with a module having a mounting board according to a technical feature of the invention is provided, which comprises a metallic heat-dissipating member including a body having a upper surface and a lower surface and a plurality of spaced-apart heat dissipating fins extending upwardly from the upper surface of the body. The body is formed at its central portion with a through hole that communicates the upper surface with the lower surface. The through hole is adapted for receiving a protrusion block that protrudes from a back surface of the mounting board of the module opposite to amounting surface on which electrical devices are mounted. The device further comprises a pump unit including an accommodating case disposed in a pump mounting region located on the upper surface of the body of the heat-dissipating member and filled with a coolant fluid, a set of pump blades disposed inside of the accommodating case and arranged at a lower end of a rotary shaft extending downwardly from a top wall of the accommodating case, and a passive magnet disposed at an upper end of the rotary shaft. The device further comprises a fluid conduit filled with the same coolant fluid as that filled within the accommodating case of the pump unit. The fluid conduit is in fluid communication with the accommodating case, so that the coolant fluid is allowed to circulate between the fluid conduit and the accommodating case. The device further comprises a fan unit disposed on the heat dissipating fins of the metallic heat dissipating member and including a driving shaft having a lower end extending downwardly close to the passive magnet, and an active magnet mounted at the lower end of the driving shaft. When the fan unit is activated, the active magnet is rotated with the driving shaft, so that the passive magnet is rotated with the active magnet by which the pump blades are driven to rotate, whereby the coolant fluid filled in the fluid conduit is circulated at high speed.

According to another technical feature of the invention, a heat dissipating device is provided. The heat dissipating device is adapted for use in combination with a module provided with amounting board, which comprises: a first metallic heat dissipating member including a body having a upper surface and a lower surface and a plurality of spaced-apart heat dissipating fins extending upwardly from the upper surface of the body, wherein the body is formed at the upper surface thereof with a pump unit installation recess; a pump unit including an accommodating case disposed in the pump unit installation recess of the body of the first metallic heat dissipating member and filled with a coolant fluid, a set of pump blades disposed inside of the accommodating case and arranged at a lower end of a rotary shaft extending downwardly from a top wall of the accommodating case, and a passive magnet disposed at an upper end of the rotary shaft; a fan unit disposed on the heat dissipating fins of the first metallic heat dissipating member and including a driving shaft having a lower end extending downwardly close to the passive magnet, and an active magnet mounted at the lower end of the driving shaft, wherein when the fan unit is activated, the active magnet is rotated with the driving shaft, so that the passive magnet is rotated with the active magnet; a second metallic heat dissipating member disposed aside the first metallic heat dissipating member, including a body mounted on a surface of the mounting board of the module, the body being provided with a plurality of upwardly extending heat dissipating fins and having a lower surface formed with an accommodating recess at a position corresponding to the module; and a fluid conduit filled with the same coolant fluid as that filled within the accommodating case of the pump unit, wherein the fluid conduit is in fluid communication with the accommodating case, and wherein the fluid conduit has an interconnection portion configured to extend through the body of the second metallic heat dissipating member, so that the coolant fluid is allowed to circulate between the fluid conduit and the accommodating case.

According to still another technical feature of the invention, a heat dissipating device is provided. The heat dissipating device is adapted for use in combination with a module provided with a mounting board, which comprises a metallic heat dissipating member disposed on a backside of the mounting board of the module, including a generally disc-shaped body, a plurality of heat dissipating fins, each having an upper end and a lower end, and a circular collecting pipe, wherein the body has a lower surface in contact with the backside of the mounting board of the module and is formed inside with a collecting annulus extending along the periphery thereof and has an upper surface formed with a pump unit installation recess, and wherein the heat dissipating fins extend upwardly from the upper surface of the body and radially arranged along the periphery of the body in a manner spaced apart from one another, each being formed with at least one channel that extends from the upper end to the lower end thereof and coupled in fluid communication with the collecting annulus, and wherein the circular collecting pipe is disposed at the upper ends of the heat dissipating fins and coupled in fluid communication with the channels of the heat dissipating fins; a fan unit including a driving shaft, a set of fan blades and an active magnet, wherein the driving shaft has a lower end extending close to the body, and wherein the fan blades are mounted at an upper end of the driving shaft in such a manner that when the driving shaft is driven to rotate, the fan blades are rotated with the driving shaft, and wherein the active magnet is mounted at a lower end of the driving shaft in such a manner that the active magnet is rotatable with the driving shaft; a pump unit including an accommodating case, a set of pump blades and a passive magnet, wherein the accommodating case 20 is disposed in the pump unit installation recess 104 of the body, so that the accommodating case has a top wall positioned close to the active magnet, and wherein the pump blades are arranged at a lower end of amounting shaft extending downwardly from the top wall of the accommodating case, and wherein the passive magnet is disposed at an upper end of the mounting shaft at a position close to the top wall of the accommodating case and further connected to the pump blades, such that the passive magnet is rotatable with the pump blades; an outlet conduit having an input end provided inside of the body and in fluid communication with a fluid output port of the accommodating case, and an output end extending upwardly and provided in fluid communication with the collecting pipe; and an inlet conduit disposed within the body, having an output end in fluid communication with a fluid input port of the accommodating case and an input end in fluid communication with the collecting annulus.

According to still another technical feature of the invention, a heat dissipating device is provided. The heat dissipating device is adapted for use in combination with a module provided with a transparent mounting board and a plurality of light-emitting diodes mounted on a mounting surface of the mounting board, which comprises: a thermally conductive unit including a mounting substrate, and a plurality of conductors disposed on the mounting substrate, wherein the mounting substrate has a first mounting surface and a second mounting surface which is opposite to the first mounting surface and overlaid with predetermined circuit traces, and wherein each of the conductors includes a first terminal electrically connected to the corresponding circuit traces provided on the second mounting surface of the mounting substrate and a second terminal electrically connected to one of the light-emitting diodes located in the module, so that when the respective conductors are provided with electric power, the second terminals have a lower temperature as compared to the first terminals, thereby reducing the working temperature of the light-emitting diodes; and a fan unit mounted on the first mounting surface of the mounting substrate.

According to still another technical feature of the invention, a light-emitting diode module is provided. The light-emitting diode module comprises: a transparent mounting board; a plurality of light-emitting diodes mounted on a mounting surface of the mounting board; a plurality of lenses mounted on a back surface of the mounting board opposite to the mounting surface at positions corresponding to the light-emitting diodes; a thermally conductive unit including a mounting substrate, and a plurality of conductors disposed on the mounting substrate, wherein the mounting substrate has a first mounting surface and a second mounting surface which is opposite to the first mounting surface and overlaid with predetermined circuit traces, and wherein each of the conductors includes a first terminal electrically connected to the corresponding circuit traces provided on the second mounting surface of the mounting substrate and a second terminal electrically connected to one of the light-emitting diodes located in the module, so that when the respective conductors are provided with electric power, the second terminals have a lower temperature as compared to the first terminals, thereby reducing the working temperature of the light-emitting diodes; and a fan unit mounted on the first mounting surface of the mounting substrate.

According to a yet still another technical feature of the invention, a solar cell module is provided. The solar cell module comprises a transparent mounting board; a transparent conductive layer mounted on amounting surface of the mounting board; a plurality of solar cells mounted on the mounting surface of the mounting board by means of the transparent conductive layer; a plurality of lenses mounted on a back surface of the mounting board opposite to the mounting surface at positions corresponding to the solar cells; a thermally conductive unit including a mounting substrate, and a plurality of conductors disposed on the mounting substrate, wherein the mounting substrate has a first mounting surface and a second mounting surface which is opposite to the first mounting surface and overlaid with predetermined circuit traces, and wherein each of the conductors includes a first terminal electrically connected to the corresponding circuit traces provided on the second mounting surface of the mounting substrate and a second terminal electrically connected to one of the solar cells located in the module, so that when the respective conductors are provided with electric power, the second terminals have a lower temperature as compared to the first terminals, thereby reducing the working temperature of the solar cells; and a fan unit mounted on the first mounting surface of the mounting substrate.

### BRIEF DESCRIPTION OF THE DRAWINGS

The above and other objects, features and effects of the invention will become apparent with reference to the following description of the preferred embodiments taken in conjunction with the accompanying drawings, in which:

FIGS. 1 to 3 are schematic diagrams illustrating the heat dissipating device according to the first preferred embodiment of the invention;

FIGS. 4 to 5 are schematic diagrams of alternative examples of the LED modules using the heat dissipating device according to the invention, showing that some of the electrical elements used therein are modified;

FIGS. 6 to 8 are schematic diagrams of the heat dissipating device according to the second preferred embodiment of the invention;

FIG. 9 is a schematic circuit block diagram for the safety protection device used in the heat dissipating device of the invention;

FIGS. 10 and 11 are schematic diagrams of the heat dissipating device according to the third preferred embodiment of the invention;

FIGS. 12 to 14 are schematic diagrams of assistant heat dissipating members suitable for use in the heat dissipating device of the invention;

FIGS. 15 to 19 are schematic diagrams of the heat dissipating device according to the fourth preferred embodiment of the invention;

FIG. 20 is a schematic cross-sectional view of the heat dissipating device according to the fifth preferred embodiment of the invention;

FIG. 21 is a schematic cross-sectional view of the heat dissipating device according to the sixth preferred embodiment of the invention;

FIG. 22 is a schematic cross-sectional view of an alternative example of the heat dissipating device according to the first preferred embodiment of the invention;

FIGS. 23A and 23B are schematic diagrams of an alternative example of the heat dissipating device according to the sixth preferred embodiment of the invention;

FIG. 24 is a schematic cross-sectional view of an alternative example of the heat dissipating device according to the sixth preferred embodiment of the invention;

FIGS. 25A and 25B are schematic diagrams of another alternative example of the heat dissipating device according to the sixth preferred embodiment of the invention;

FIG. 26 is a schematic exploded view of another alternative example of the heat dissipating device according to the sixth preferred embodiment of the invention;

FIG. 27 is a schematic cross-sectional diagram, showing that the heat dissipating device according to the invention is used in combination with a memory module; and

FIG. 28 is a schematic cross-sectional view of an alternative example of the heat dissipating device according to the first preferred embodiment of the invention.

### DETAILED DESCRIPTION OF THE PREFERRED EMBODIMENTS

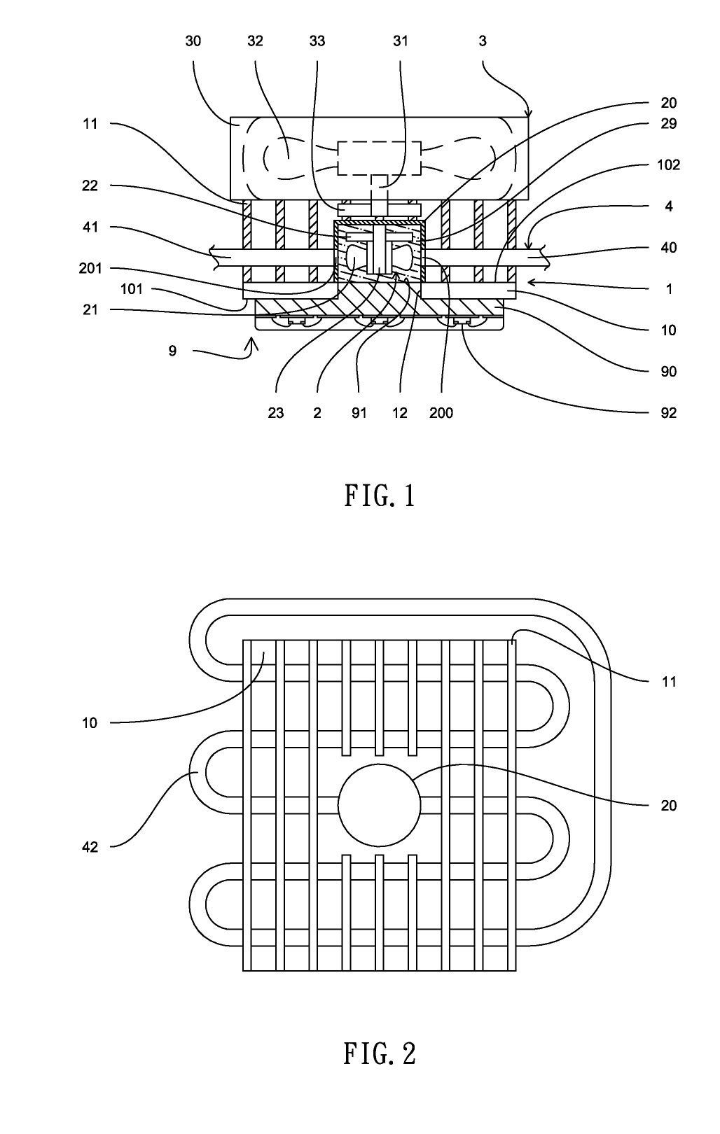

FIGS. 1 to 3 are schematic diagrams illustrating the heat dissipating device according to the first preferred embodiment of the invention. In FIG. 3, the fan blades 32 of the fan unit 3 are removed from the mounting frame 30 for clarity.

Referring to FIGS. 1-3, the heat dissipating device according to the first preferred embodiment of the invention generally comprises a metallic heat-dissipating member 1, a pump unit 2, a fluid conduit 4 and a fan unit 3.

The metallic heat-dissipating member 1 includes a generally rectangular-shaped body 10 and a plurality of spaced-apart heat dissipating fins 11 extending upwardly from an upper surface 102 of the body 10. The body 10 is formed at its central portion with a through hole 12 that communicates the upper surface 102 with a lower surface 101 of the body 10. In this embodiment, the through hole 12 is adapted for receiving a protrusion block 91 that protrudes from a back surface of a mounting board 90 of a light-emitting diode module 9, the back surface being opposite to the mounting surface on which light-emitting diodes 92 are mounted. In other words, the heat dissipating device disclosed herein is arranged to reducing the working temperature of the LED module 9.

In this embodiment, the heat-dissipating member 1 is made of aluminum. However, the heat-dissipating member 1 can alternatively be made of any material suitable for the heat-dissipating purpose. In addition, the upper surface 102 of the body 10 includes a central region on which a pump is mounted and, hence, there is no heating dissipating fin 11 installed in the pump mounting region, as shown in FIGS. 1 and 2.

The pump unit 2 includes an accommodating case 20, a set of pump blades 21 and a passive magnet 22.

The accommodating case 20 is disposed in the pump mounting region of the upper surface 102 of the body 10 of the heat-dissipating member 1 in such a manner that the interior space of the accommodating case 20 is accessible through the through hole 12 of the body 10. The accommodating case 20 is further provided with a fluid input port 200 and a fluid output port 201. The interior space of the accommodating case 20 is filled with a coolant fluid 29. In this embodiment, the accommodating case 20 is preferably made from metal material. However, the accommodating case 20 can alternatively be made of any other suitable material.

The pump blades 21 are disposed inside of the accommodating case 20 and arranged at a lower end of a rotary shaft 23 extending downwardly from a top wall of the accommodating case 20. In this embodiment, the pump blades 21 are preferably made from metal material. However, the pump blades 21 can alternatively be made of any other suitable material, such as a plastic material.

The passive magnet 22 is installed at an upper end of the rotary shaft 23 at a position close to the top wall of the accommodating case 20.

The fluid conduit 4 is filled with the same coolant fluid 29 as that filled within the accommodating case 20 of the pump unit 2. The fluid conduit 4 is equipped with a fluid outlet 40 in fluid communication with the fluid input port 200 of the accommodating case 20, a fluid inlet 41 in fluid communication with the fluid output port 201 of the accommodating case 20, and an interconnection portion 42 coupled in fluid communication with both of the fluid outlet 40 and the fluid inlet 41 and extending in a meandering manner through the heating dissipating fins 11 (see FIG. 2). By virtue of this arrangement, when the pump blades 21 of the pump unit 2 are rotated, the coolant fluid 29 is propelled to circulate within the fluid conduit 4 and the accommodating case 20.

The fan unit 3 includes a mounting frame 30, a driving shaft 31 arranged perpendicular to the body 10, a set of fan blades 32, and an active magnet 33.

The mounting frame 30 is disposed on the heat dissipating fins 11 of the metallic heat dissipating member 1 by any suitable process known in the art.

The driving shaft 31 is rotatably installed in the mounting frame 30 and driven by a motor (not shown). The driving shaft 31 is registered with the mounting shaft 23 of the pump unit 2 and the lower end thereof extends downwardly close to the top wall of the accommodating case 20 of the pump unit 2.

The fan blades 32 are mounted at an upper end of the driving shaft 31 in such a manner that when the driving shaft 31 is driven to rotate, the fan blades 32 are rotated with the driving shaft 31. It should be noted that the fan blades 32 are adapted for being rotated at a rotation speed of thousands revolutions per minute according to this embodiment.

The active magnet 33 is mounted at the lower end of the driving shaft 31, so that it is rotatable with the driving shaft 31. Owing to the magnetic force, the rotation of the active magnet 33 causes the passive magnet 22 of the pump unit 2 to rotate, thereby in turn causing the pump blades 21 to rotate.

By virtue of the arrangement described above, the fluid conduit 4 is brought in contact with the body 10 and heat dissipating fins 11 of the heat dissipating member 1. As such, when the fan blades 32 of the fan unit 3 are rotated at a high speed of thousands rpm, the active magnet 33 and the passive magnet 22 are both rotated at high speed with the fan blades 32, such that the pump blades 21 are rotated at high speed to effect a high-speed circulation of the coolant fluid 29 within the fluid conduit 4. The temperature of the LED module 9 is reduced by the heat exchange of the coolant fluid 29 inside the fluid conduit 4 with the body 10 and heat dissipating fins 11.

Since the fan blades 32 are rotated at high speed, the pump blades are similarly rotated at high speed, such that the fluid flows rapidly within the fluid conduit 4 to achieve heat exchange with high efficiency. Moreover, since the interconnection portion 42 of the fluid conduit 4 is configured to extend in a meandering manner through the body 10 and the heating dissipating fins 11 of the heat dissipating member 1, the contact area between the fluid conduit 4 and the body 10 and heating dissipating fins 11 of the heat dissipating member 1 is increased, whereby the heat dissipating efficiency is enhanced. In addition, the high-speed agitation of the coolant fluid 29 within the accommodating case 20 by the pump blades 21 further generates a cooling effect on the coolant fluid 29.

On the other hand, the upward or downward air flow generated by the fan blades 32 causes air convection which will enhance the cooling effect further.

The coolant fluid 29 filled within the fluid conduit 4 may optionally be water, water supplemented with a coolant solution, water supplemented with a liquid having a low combustion point and the like. For example, the coolant fluid 29 can contain 50% alcohol and 50% water. Particularly preferred is a coolant fluid 29 supplemented with a liquid having a low combustion point, in view of its natural tendency of being gasified. That is, the coolant fluid 29 of this type, when gasified, exhibits an elevated flow speed and, therefore, an enhanced heat change efficiency. Meanwhile, since the coolant fluid 29 is a mixture having a significant water content, it does not present any risk to safety. Alternatively, the coolant fluid 29 is a gas.

Further, given the inventive design, in which the driving shaft 31 of the fan unit 3 is registered with the mounting shaft 23 of the pump unit 2 and the active magnet 32 is prevented from having direct contact with the passive magnet 22, the fluid conduit 4 and the accommodating case 20 of the pump unit 2 can be tailored to have a vacuum interior space, so as to prevent the coolant fluid 29 filled within the fluid conduit 4 and the accommodating case 20 of the pump unit 2 from leakage.

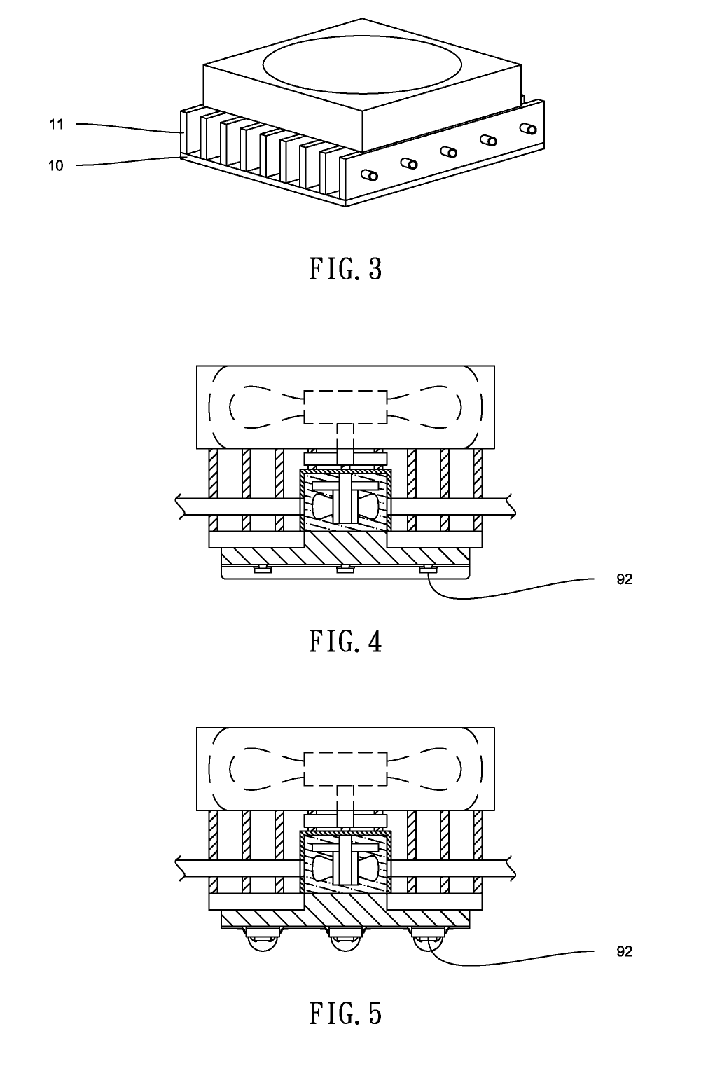

In FIG. 1, the respective LED packages 92 are wire bonded to the LED module 9. However, the LED packages 92 can alternatively be flip-chip bonded to the module as shown in FIG. 4, or the LED packages 92 are commercially available emitters as shown in FIG. 5.

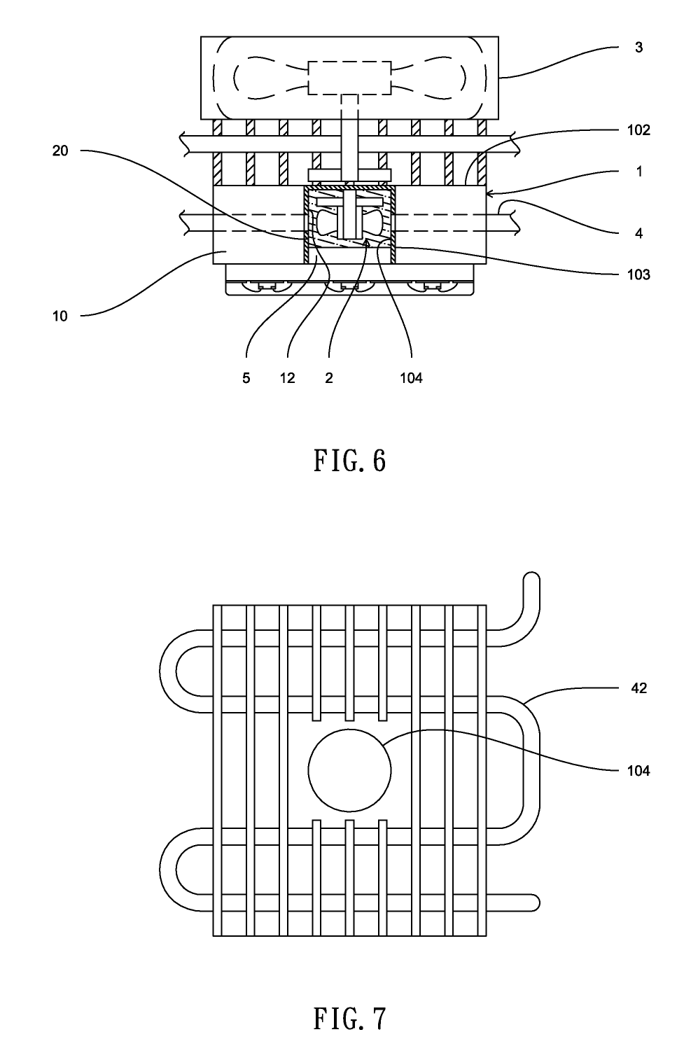

FIGS. 6 to 8 are schematic diagrams of the heat dissipating device according to the second preferred embodiment of the invention. FIG. 6 is a schematic side view of the heat dissipating device according to the second preferred embodiment of the invention. FIG. 7 is a schematic top view of the device, in which the fan unit is omitted for brevity. FIG. 8 is another schematic top view of the device, in which the fan unit and heat dissipating fins are omitted for brevity.

Referring to the embodiment shown in FIGS. 6-8, the accommodating case 20 of the pump unit 2 is disposed within the through hole 12. The pump unit 2 according to this embodiment has the same configuration as that described in the first preferred embodiment and, thus, is not repeated herein. Further, the interconnection portion 42 of the fluid conduit 4 does not only pass through the heat dissipating fins 11, but also through the body 10.

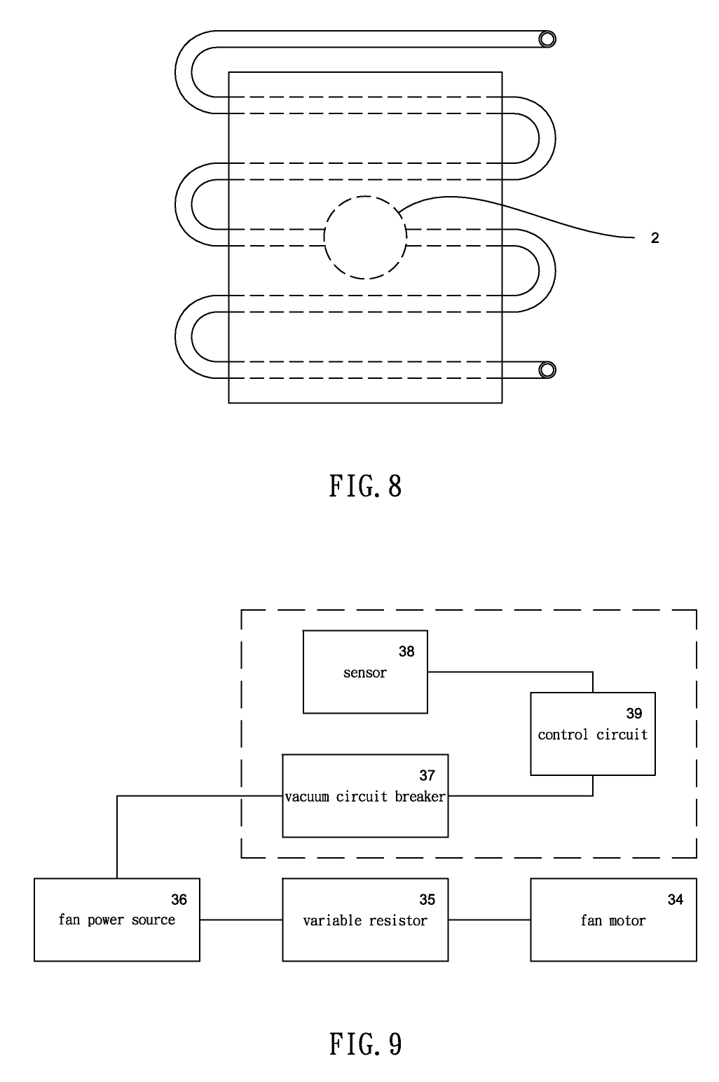

FIG. 9 is a schematic circuit block diagram for the safety protection device used in the heat dissipating device of the invention.

As shown in FIG. 9, the safety protection device generally includes a PTR temperature variable resistor 35 coupled in series between a fan motor 34 and a fan power source 36 of the fan unit 3, a vacuum circuit breaker 37 electrically connected to the fan power source, a control circuit 39 electrically connected to the circuit breaker 3 7, and a sensor 3 8 electrically connected to the control circuit 39 and adapted for detecting the rotation speed of the fan motor 34.

The variable resistor 35 is one whose electrical resistance varies in inverse proportion to temperature. The variable resistor 35 is disposed on the body 10 of the heat dissipating member 1, so that the electrical resistance thereof is varied in inverse proportion to the temperature of the body 10 of the heat dissipating member 1. In other words, the electrical resistance value of the variable resistor 35 is reduced as the temperature of the body 10 of the heat dissipating member 1 goes up, thereby rendering the fan motor 34 to drive the fan blades 32 to rotate at higher speed. On the other hand, when the temperature of the body 10 of the heat dissipating member 1 goes down, the electrical resistance value of the variable resistor 35 is increased, so that the fan motor 34 drives the fan blades 32 to rotate at lower speed.

The circuit breaker 37 is operable to interrupt power supply from the fan power source 36.

The sensor 38 is employed to generate a detection signal indicative of the rotation speed of the fan motor 34 upon detecting the rotation speed of the fan motor 34. The control circuit 39 receives the detection signal and compares the same with a reference signal representing a normal rotation speed of the motor. When the detection signal is found to be greater than the reference signal, it indicates that the motor 34 is rotated at a higher speed than the normal rotation and water leakage occurs. In this case, the control circuit 39 will output an activating signal to the circuit breaker 37, so that the circuit breaker 37 is activated to interrupt power supply from the fan power source 36 to secure safety.

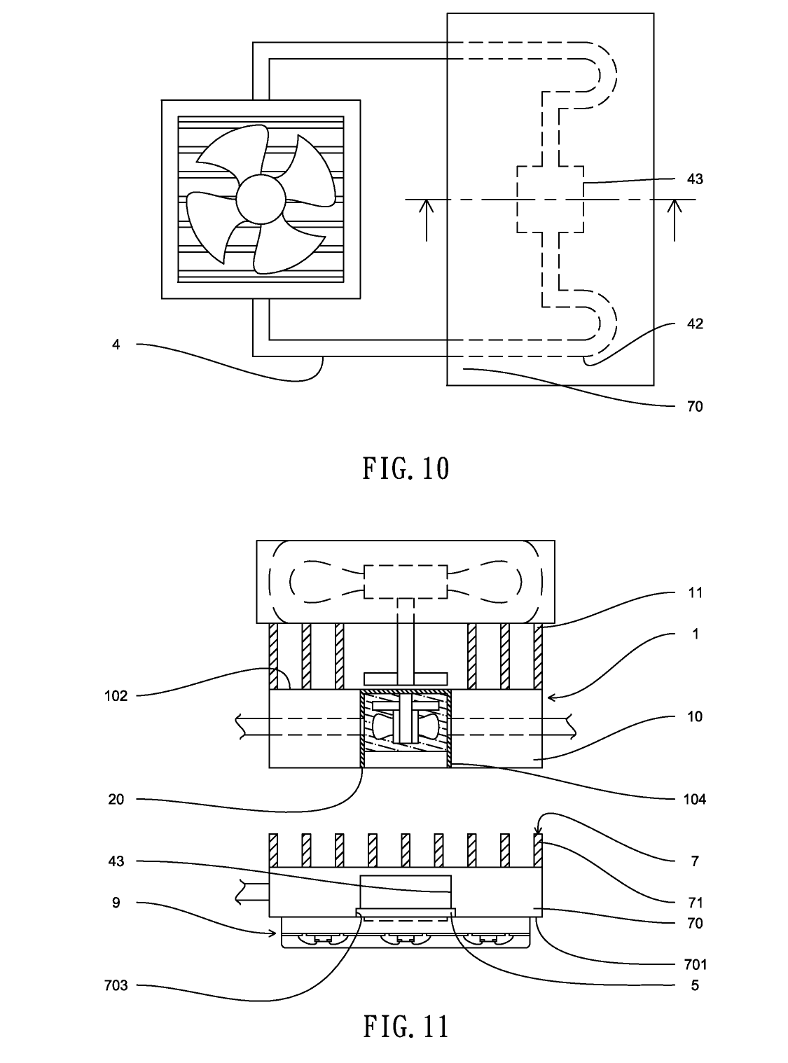

FIGS. 10 and 11 are schematic diagrams of the heat dissipating device according to the third preferred embodiment of the invention.

As shown in FIGS. 10 and 11, the heat dissipating device according to the third preferred embodiment of the invention generally includes a first metallic heat dissipating member 1, a pump unit 2, a fan unit 3, a fluid conduit 4 and a second metallic heat dissipating member 7.

The second metallic heat dissipating member 7 comprises a body 70 mounted on a surface of the LED module 9. The body 70 is provided with a number of upwardly extending heat dissipating fins 71 and has a lower surface 701 formed with an accommodating recess 703 at a position corresponding to the LED module 9.

An assistant heat dissipating pad 5, which may by way of example be made of copper, is disposed within the accommodating recess 703 of the body 70 in such a manner that the assistant heat dissipating pad 5 contacts the backside of the mounting board 90 of the LED module 9, thereby enhancing the heat exchange between the heat dissipating member 7 and the LED module 9. A reservoir 43 is formed at the interconnection portion 42 of the fluid conduit 4 in a manner corresponding to the assistant heat dissipating pad 5, so as to allow heat exchange of the coolant fluid 29 filled in the reservoir 43 with the assistant heat dissipating pad 5, thereby reducing the working temperature of the LED module 9 further.

The first metallic heat dissipating member 1 includes a body 10 disposed on the second metallic heat dissipating member 7 and a number of upwardly extending heat dissipating fins 11. The body 10 is formed at its upper surface 102 with a pump unit installation recess 104 for receiving the accommodating case 20 of the pump unit 2. The rest parts of the pump unit 2 according to this embodiment have the same configurations as those shown in FIGS. 1 and 6 and, thus, are not repeated herein.

The fan unit 3 described in this embodiment has the same configuration as those shown in FIGS. 1 and 6 and, thus, is not repeated herein.

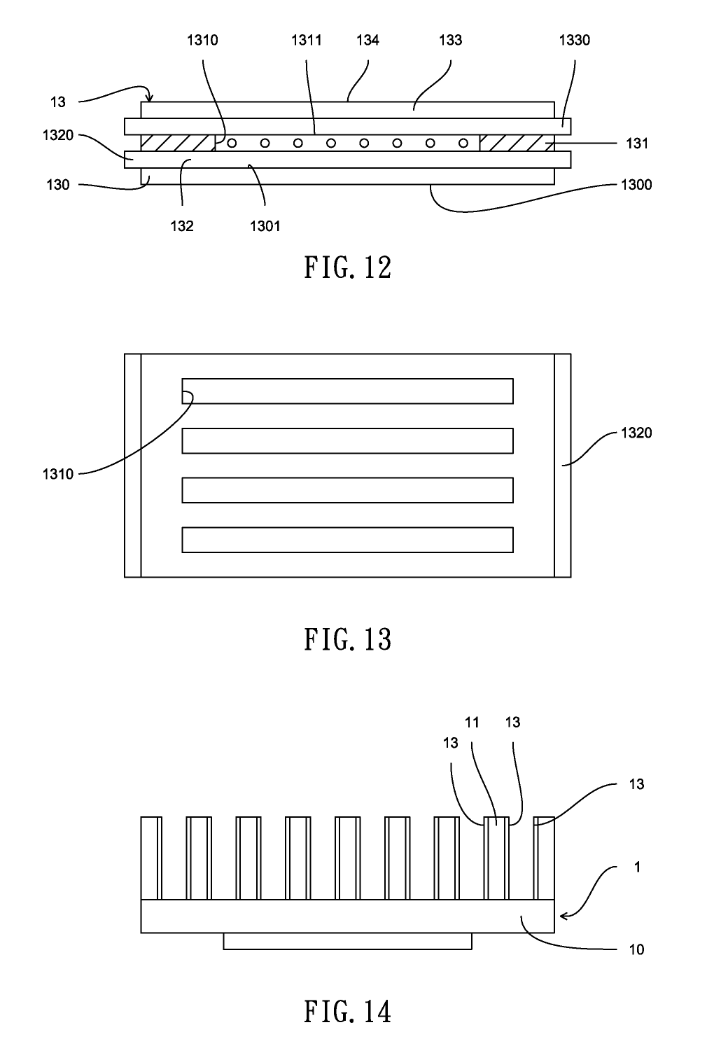

FIGS. 12 to 14 are schematic diagrams of assistant heat dissipating members suitable for use in the heat dissipating device of the invention.

As shown in FIGS. 12 to 14, the respective assistant heat dissipating members 13 are attached to surfaces of the heat dissipating fins 11 of the metallic heat dissipating member 1.

The assistant heat dissipating members 13 may by way of example be configured in the form of the so-called heat pipes, each includes a bottom layer 130, an intermediate layer 131, a first copper foil 132 and a second copper foil 133, and a top layer 134.

The bottom layer 130 is a flexible film made of a polyimide (PI) and a butadiene-styrene copolymer (BS). The bottom layer 130 has a first surface 1300 intimately attached to a surface of a corresponding heat dissipating fin 11 and a second surface 1301 opposite to the first surface 1300. The first copper foil 132 is placed on the second surface 1301 by, for example, printing, with both ends 1320 extending beyond the edges of the bottom layer 130. It should be noted that the first copper foil 132 can be substituted with any suitable metal foil.

The intermediate layer 131 is formed on the first copper foil 132. According to this embodiment, the intermediate layer 131 is made of photoresist material. The intermediate layer 131 is formed with a number of slots 1310 which extend from one end to the other end of the intermediate layer 131 and extend all the way through the thickness of the intermediate layer 131. The intermediate layer 131 is subjected to a sintering process, so that the respective slots 1310 are formed at walls thereof with a plurality of apertures 1311.

The second copper foil 133 is disposed on the intermediate layer 131 by the same way as described for the first copper foil 132. Likewise, both ends 1330 of the second copper foil 133 extend beyond the edges of the intermediate layer 131.

The top layer 134 is made of the same material as described above for the bottom layer 130 and disposed on the second copper foil 133.

Both ends 1320,1330 of the first and second copper foils 132,133 of the respective assistant heat dissipating members 13 are in contact with corresponding heat dissipating fins 11 and the body 10.

By virtue of the arrangement described above, the first and second copper foils 132,133 are allowed to perform heat exchange with the body 10 and the heat dissipating fins 11, thereby enhancing the heat dissipation effect. It should be noted that the apertures 1310 of the intermediate layer 131 may be filled with a fluid having a low combustion point, so that the fluid is rapidly gasified when the first and second copper foils 132,133 perform heat exchange with the body 10 and the heat dissipating fins 11. The gasified low combustion point fluid will later return back to the liquid form in the apertures 1310 due to capillary condensation.

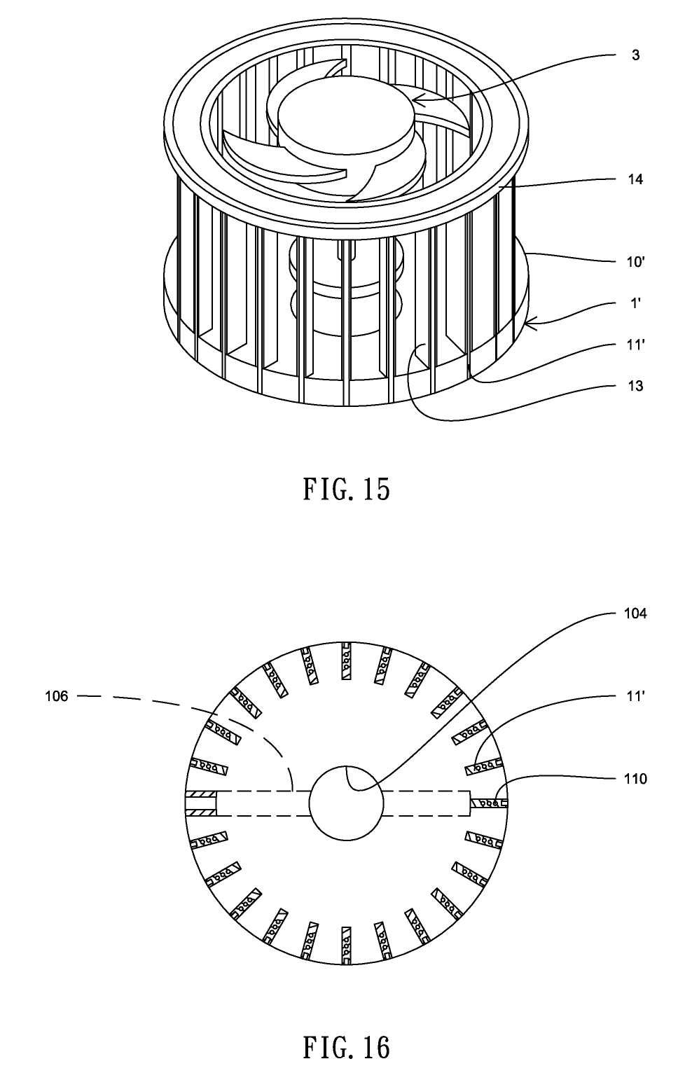

FIGS. 15 to 19 are schematic diagrams of the heat dissipating device according to the fourth preferred embodiment of the invention.

According to the embodiment shown in FIGS. 15 to 19, the heat dissipating device disclosed herein generally comprises a metallic heat dissipating member 1′, a fan unit 3, a pump unit 2, a L-shaped outlet conduit 106, an inlet conduit 107, and a plurality of assistant heat dissipating members 13.

The metallic heat dissipating member 1′ is disposed on the backside of the mounting board 90 of the LED module 9 and includes a generally disc-shaped body 10′, a plurality of heat dissipating fins 11′, and a circular collecting pipe 14.

The body 10′ has a lower surface 101′ in contact with the backside of the mounting board 90 of the LED module 9. Meanwhile, as shown in FIG. 19, the body 10′ is formed inside with a collecting annulus 105 extending along the periphery thereof. A pump unit installation recess 104 is formed on the upper surface 102′ of the body 10.

The plurality of heat dissipating fins 11′ extend upwardly from the upper surface 102′ of the body 10′ and radially arranged along the periphery of the body 10′ in a manner spaced apart from one another. Each of the heat dissipating fins 11′ is formed with at least one channel 110 that extends from the upper end to the lower end thereof and is coupled in fluid communication with the collecting annulus 105.

The circular collecting pipe 14 is disposed at the upper ends of the heat dissipating fins 11′ and coupled in fluid communication with the channels 110 of the heat dissipating fins 11′.

The fan unit 3 includes a mounting frame 30, a driving shaft 31 arranged perpendicular to the body 10′, a set of fan blades 32, and an active magnet 33.

The mounting frame 30 is surrounded by and connected to the heat dissipating fins 11′, so that it is held at a height close to that of the circular collecting pipe 14.

The driving shaft 31 is rotatably installed in the mounting frame 30 as described in the embodiments above. The driving shaft 31 has a lower end extending downwardly close to the body 10′.

The fan blades 32 are mounted at an upper end of the driving shaft 31 in such a manner that when the driving shaft 31 is driven to rotate, the fan blades 32 are rotated with the driving shaft 31.

The active magnet 33 is mounted at the lower end of the driving shaft 31, so that it is rotatable with the driving shaft 31.

The pump unit 2 includes an accommodating case 20, a set of pump blades 21 and a passive magnet 22.

The accommodating case 20 is disposed in the pump unit installation recess 104 of the body 10′, so that the top wall of the accommodating case 20 is positioned close to the active magnet 33. The accommodating case 20 is provided with a fluid input port 200 and a fluid output port 201. In this embodiment, the accommodating case 20 is preferably made from metal material.

The pump blades 21 are rotatably arranged at the lower end of the mounting shaft 23 extending downwardly from the top wall of the accommodating case 20. In this embodiment, the pump blades 21 are preferably made from metal material.

The passive magnet 22 is rotatably disposed at the upper end of the mounting shaft 23 at a position close to the top wall of the accommodating case 20. The passive magnet 22 is further connected to the pump blades 21, such that it is rotatable with the pump blades 21.

The outlet conduit 106 has an input end 1060 provided inside of the body 10′ and in fluid communication with the fluid output port 201 of the accommodating case 20, and an output end 1061 extending upwardly and provided in fluid communication with the collecting pipe 14.

The inlet conduit 107 is disposed within the body 10′ and has an output end 1070 in fluid communication with the fluid input port 200 of the accommodating case 20 and an input end 1071 in fluid communication with the collecting annulus 105.

The assistant heat dissipating members 13 have the same configuration as that shown in FIGS. 12 to 14. The respective assistant heat dissipating members 13 are attached to the lower surface 101′ of the body 10′ and extend to outer surfaces of corresponding heat dissipating fins 11′, so as to perform heat exchange with the coolant fluid 29 filled within the corresponding heat dissipating fins 11′, thereby further enhancing the heat dissipation effect.

In the arrangement described above, when the pump blades 21 are rotated in response to the rotation of the fan blades 32, the coolant fluid 29 is further delivered from the accommodating case 20 to the collecting pipe 14 through the outlet conduit 106, and further delivered to the collecting annulus 105 via the channels 110, and finally returns back to the accommodating case 20 via the inlet conduit 107.

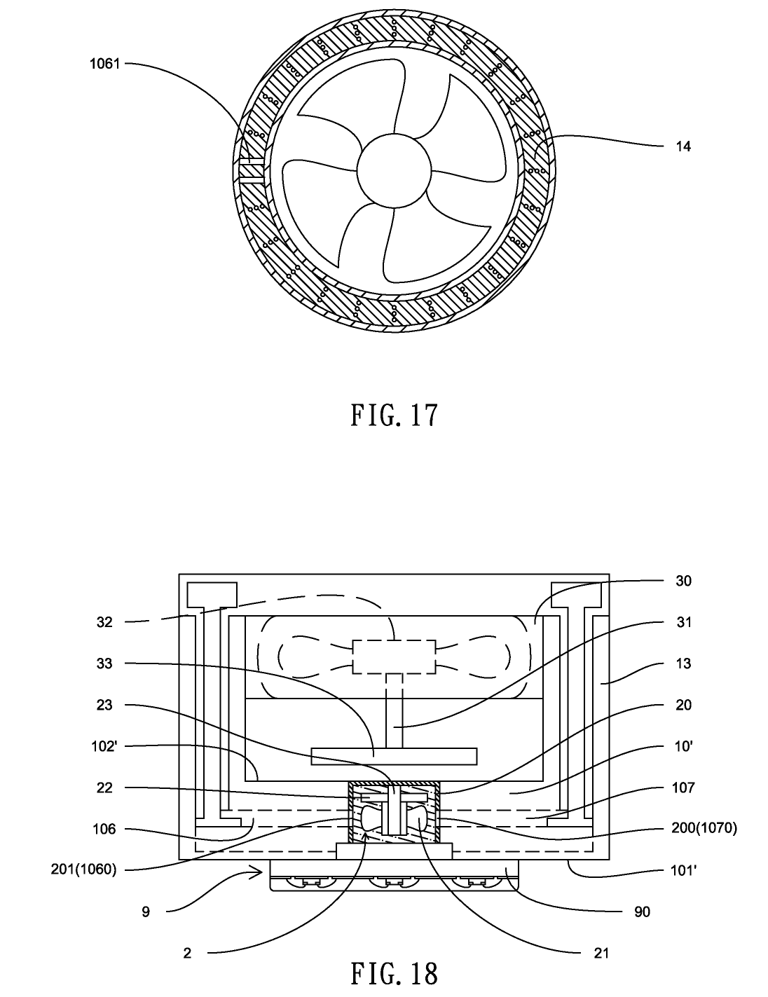

FIG. 20 is a schematic cross-sectional view of the heat dissipating device according to the fifth preferred embodiment of the invention.

According to the embodiment shown in FIG. 20, the heat dissipating device disclosed herein comprises a fan unit 3 and a thermally conductive unit 6.

The thermally conductive unit 6 includes a mounting substrate 60, and a plurality of conductors 61 disposed on the mounting substrate 60 and made of semiconductor material.

According to this embodiment, the mounting substrate 60 is a ceramic substrate having a first mounting surface and a second mounting surface which is opposite to the first mounting surface and overlaid with predetermined circuit traces 600. The fan unit 3 is mounted on the first mounting surface of the mounting substrate 60.

Each of the conductors 61 includes a first electrode 610 electrically connected to the corresponding circuit traces provided on the second mounting surface of the mounting substrate 60 and a second electrode 611 electrically connected to an LED 92 located in the LED module 9. In this embodiment, the first electrodes 610 of the respective conductors 61 are P-type electrodes, whereas the second electrodes 611 are N-type electrodes. Therefore, when the respective conductors 61 are provided with electric power via the circuit traces 600, they facilitate the heat transfer from the ends remote from the mounting substrate 60 towards the opposite ends thereof which are close to the mounting substrate 60.

The LED module 9 has a transparent mounting board 90 and a plurality of LEDs 92 operatively mounted on the mounting surface of the mounting board 90. Each of the LEDs has a first electrode 920 connected to the second electrode 611 of the corresponding conductor 61 of the conductive unit 6, and a second electrode 921 electrically connected to the corresponding circuit traces 98 provided on the mounting board 90, so as to allow the conductors 61 to reduce the working temperature of the LEDs 92.

It should be noted that the LED module 9 disclosed herein further comprises a plurality of lenses 93 mounted on a back surface of the mounting board 90 opposite to the mounting surface at positions corresponding to the LEDs 92, and a reflective plate 94 which surrounds the lenses 93. The respective lenses 93 have a single arc-shaped outer surface as shown in FIG. 20, but may alternatively be configured to have a number of flat outer surfaces.

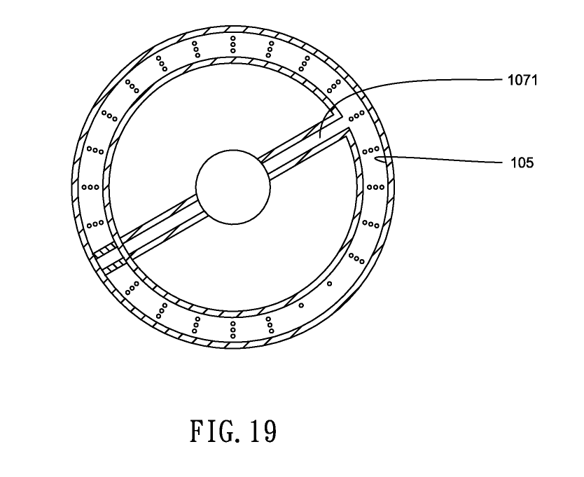

FIG. 21 is a schematic cross-sectional view of an alternative example of the heat dissipating device according to the fifth preferred embodiment of the invention, which differs from the fifth preferred embodiment in that the heat dissipating device is used in combination with a solar cell module. The solar cell module comprises a mounting board 90′, a plurality of solar cells 95 operatively mounted on a mounting surface of the mounting board 90′ by means of a transparent conductive layer 96, and a plurality of lenses 93 mounted on a back surface of the mounting board 90′ opposite to the mounting surface at positions corresponding to the solar cells 95.

It should be noted that the alternative example may be additionally include a light converging cover 900 for converging the emitted light, which is provided on the mounting board 90′ in a manner covering the lenses 93.

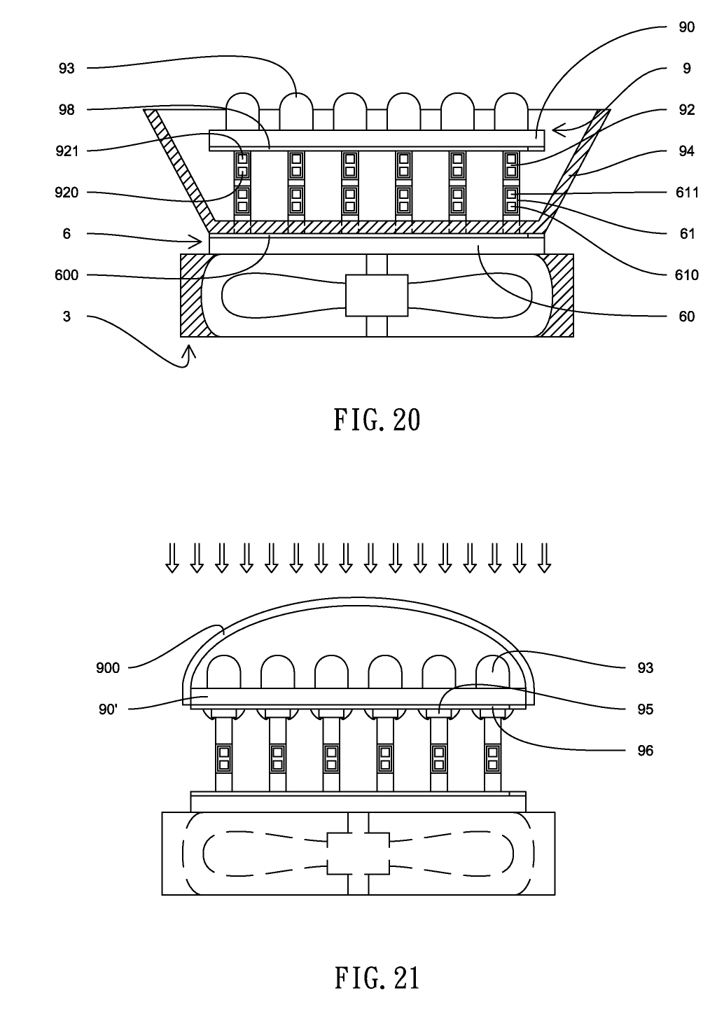

FIG. 22 is a schematic cross-sectional view of an alternative example of the heat dissipating device according to the first preferred embodiment of the invention.

The alternative example shown in FIG. 22 differs from the first preferred embodiment in that the mounting board 90 of the LED module 9 disclosed herein is a transparent mounting board, and that the LEDs 92 are operatively mounted on a surface of a protrusion block 91 extending from the backside of the mounting board 90, and that the coolant fluid 29 flowing within the accommodating case 20 and the fluid conduit 4 does not exhibit any electrical conductivity.

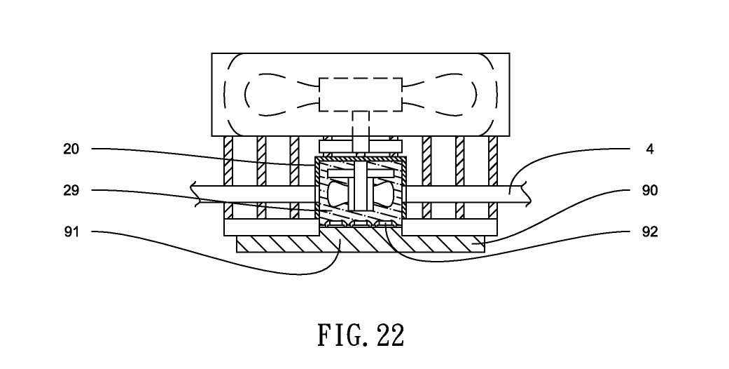

FIGS. 23A and 23B are a schematic cross-sectional view and a schematic exploded view of the heat dissipating device according to the sixth preferred embodiment of the invention, respectively.

As shown in FIGS. 23A and 23B, the heat dissipating device according to this embodiment comprises a thermally conductive unit 6. The thermally conductive unit 6 includes an elongated mounting substrate 60 with thermal conductivity. The thermally conductive mounting substrate 60 has a mounting surface on which predetermined circuit traces 62 are provided adjacent to an end of the substrate 60 (FIG. 23B illustrates only part of the circuit traces 62).

The LEDs 92 of the LED module 9 are arranged in an array and operatively mounted on the mounting surface of the mounting substrate 60, so that the electrodes of the LEDs 92 (not shown) are electrically connected to the corresponding circuit traces 62. In addition, the mounting surface of the mounting substrate 60 on which the LEDs 92 are mounted is coated with a phosphor powder layer 97 in a manner covering the LEDs 92.

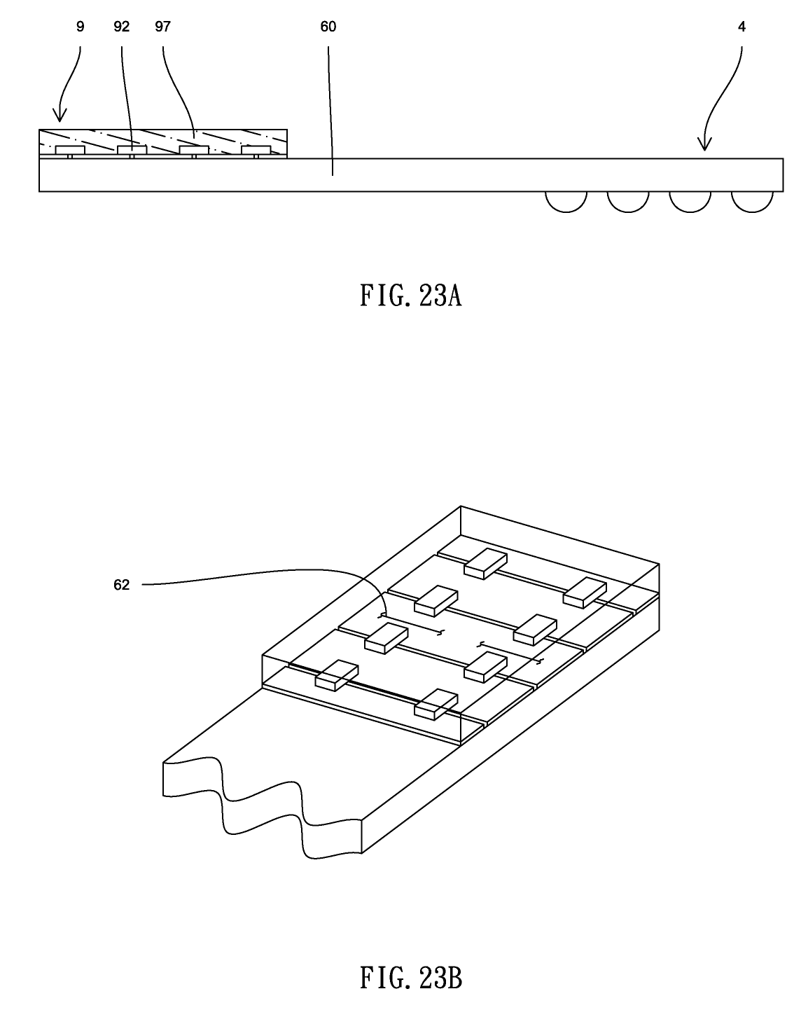

FIG. 24 is a schematic cross-sectional view of an alternative example of the heat dissipating device according to the sixth preferred embodiment of the invention.

The alternative example shown in FIG. 24 differs from the embodiment shown in FIGS. 23A and 23B in that the LEDs 92 are wire bonded to the mounting surface of the mounting substrate 60 through wires 98.

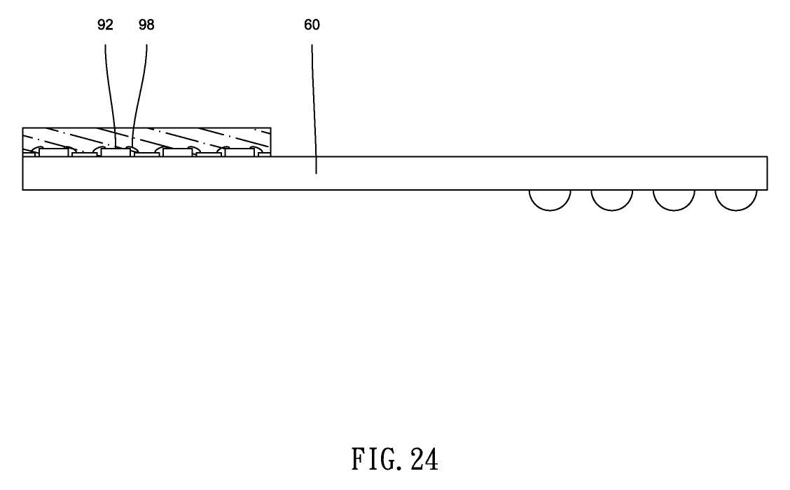

FIGS. 25A and 25B are a schematic cross-sectional view and a schematic exploded view of another alternative example of the heat dissipating device according to the sixth preferred embodiment of the invention, respectively.

The alternative example shown in FIGS. 25A and 25B differs from the embodiment shown in FIGS. 23A and 23B in that the LEDs 92 are those commercially available under the trade name Emitter Star and, hence, the phosphor powder layer shown in FIGS. 23A and 23B is omitted.

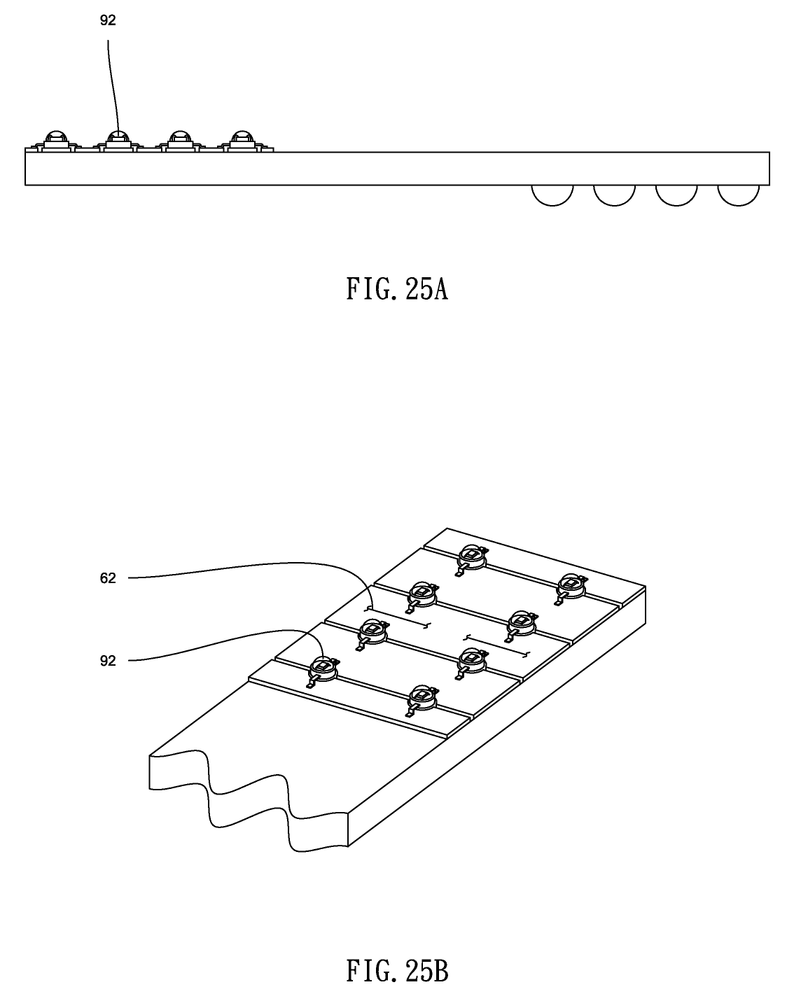

FIG. 26 is a schematic exploded view of another alternative example of the heat dissipating device according to the sixth preferred embodiment of the invention.

As shown in FIG. 26, a coolant fluid pack 63 is provided at an end of the thermally conductive mounting substrate 60 opposite to the end where the circuit traces 62 are overlaid, so that the pack 63 houses a part of the opposite end. The coolant fluid pack 63 is filled with the coolant fluid 29, so as to enhance the ability of the thermally conductive mounting substrate 60 to reduce the working temperature of LEDs 92.

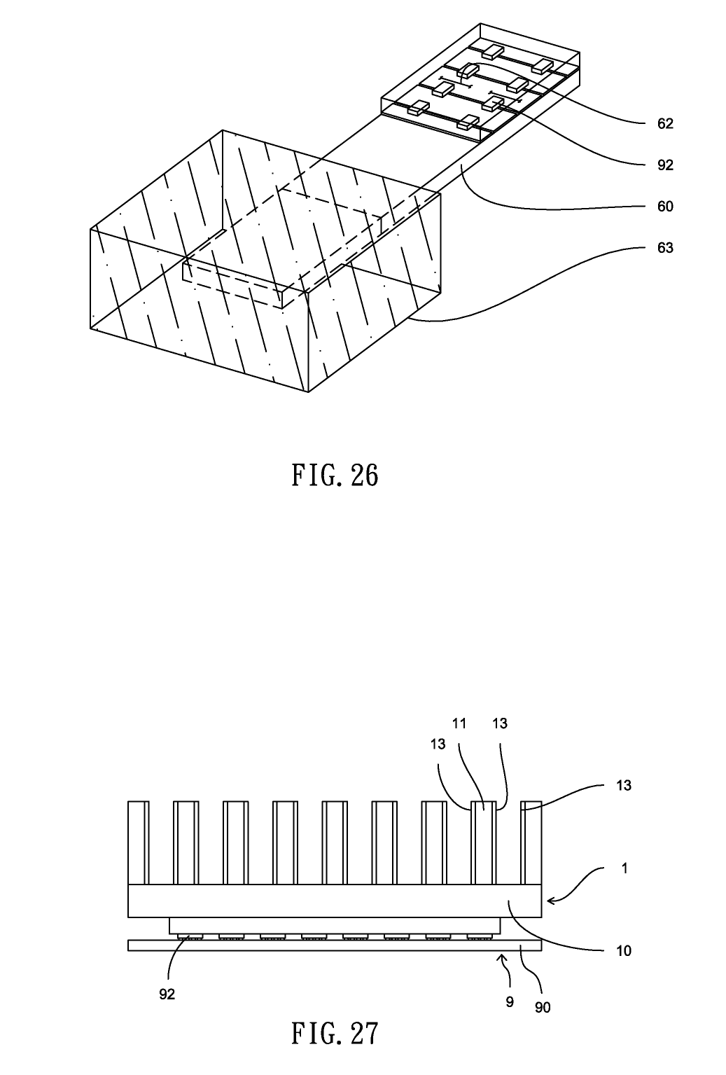

FIG. 27 is a schematic cross-sectional diagram, showing that the heat dissipating device according to the invention is used in combination with a memory module.

As shown in FIG. 27, the memory module 9 includes amounting board 90 and a plurality of memory devices 92 operatively mounted on the mounting board 90. The memory module 9 is disposed beneath the body 10, so that non-electrode mounting surfaces of the memory devices 92 are in contact with the lower surface of the body 10, thereby dissipating the heat generated due to operation of the memory module 9 through the body 10.

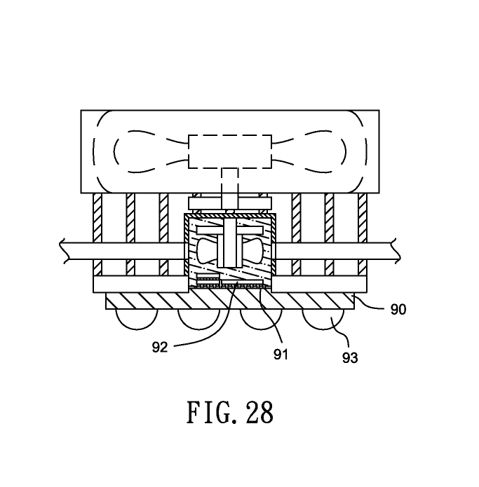

FIG. 28 is a schematic cross-sectional view of an alternative example of the heat dissipating device according to the first preferred embodiment of the invention.

The alternative example shown in FIG. 28 differs from the first preferred embodiment in that the module 9 is semiconductor integrated circuit module. The mounting board 90 of the module 9 has a lower surface on which electrically conductive linkers 93 are mounted and a number of semiconductor integrated circuits are operatively mounted on a surface of a protrusion block 91 extending from the mounting board 90.

In conclusion, the heat dissipating devices and the modules using the same as disclosed herein can surely achieve the intended objects and effects of the invention by virtue of the structural arrangements described above.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. A heat dissipating device adapted for use in combination with a module provided with a mounting board, the heat dissipating device comprising:
a first metallic heat-dissipating member including a body having a upper surface and a lower surface and a plurality of spaced-apart heat dissipating fins extending upwardly from the upper surface of the body;
a pump unit including an accommodating case disposed in a pump mounting region located on the upper surface of the body of the first heat-dissipating member and filled with a coolant fluid, a set of pump blades disposed inside of the accommodating case and arranged at a lower end of a rotary shaft extending downwardly from a top wall of the accommodating case, and a passive magnet disposed at an upper end of the rotary shaft;
a fluid conduit filled with the same coolant fluid as that filled within the accommodating case of the pump unit, wherein the fluid conduit is in fluid communication with the accommodating case, so that the coolant fluid is allowed to circulate between the fluid conduit and the accommodating case; and
a fan unit disposed on the heat dissipating fins of the metallic heat dissipating member and including a driving shaft having a lower end extending downwardly close to the passive magnet, and an active magnet mounted at the lower end of the driving shaft, wherein when the fan unit is activated, the active magnet is rotated with the driving shaft, so that the passive magnet is rotated with the active magnet by which the pump blades are driven to rotate, whereby the coolant fluid filled in the fluid conduit is circulated at high speed.

2. The heat dissipating device according to claim 1, wherein:
the fan unit further comprises a set of fan blades mounted at an upper end of the driving shaft in such a manner that the fan blades are rotated with the driving shaft, wherein the rotation of the fan blades generates a upward or downward air flow, causing air convection to enhance cooling effect.

3. The heat dissipating device according to claim 1, wherein the fluid conduit has an interconnection portion configured to extend in a meandering manner through the body and the heating dissipating fins of the first metallic heat-dissipating member, and wherein the coolant fluid is selected from the group consisting of water, water supplemented with a coolant solution, water supplemented with a liquid having a low combustion point and the like.

4. The heat dissipating device according to claim 1, further comprising a safety protection device, the safety protection device comprising:
a platinum temperature variable resistor (PTR) coupled in series between a fan motor and a fan power source of the fan unit, wherein the variable resistor has an electrical resistance value variable depending upon the temperature of the body of the metallic heat dissipating member;
a vacuum circuit breaker electrically connected to the fan power source and being operable to interrupt power supply from the fan power source;
a control circuit electrically connected to the circuit breaker; and
a sensor electrically connected to the control circuit and adapted for detecting a rotation speed of the fan motor, wherein the sensor generates a detection signal indicative of the rotation speed of the fan motor upon detecting the rotation speed of the fan motor, and the control circuit receives the detection signal and compares the same with a reference signal representing a normal rotation speed of the motor, and wherein when the detection signal is found to be greater than the reference signal, indicating that the motor is rotated at a higher speed than the normal rotation speed and water leakage occurs, the control circuit outputs an activating signal to the circuit breaker, so that the circuit breaker is activated to interrupt power supply from the fan power source to secure safety.

5. The heat dissipating device according to claim 1, wherein the pump mounting region is configured as a pump unit installation recess; and
wherein the heat dissipating device further comprises a second metallic heat dissipating member disposed aside the first metallic heat dissipating member, including a body mounted on a surface of the mounting board of the module, the body being provided with a plurality of upwardly extending heat dissipating fins and having a lower surface formed with an accommodating recess at a position corresponding to the module; and
wherein the fluid conduit has an interconnection portion configured to extend through the body of the second metallic heat dissipating member.

6. The heat dissipating device according to claim 5, further comprising an assistant heat dissipating pad disposed within the accommodating recess of the body of the second metallic heat dissipating member in such a manner that the assistant heat dissipating pad is in contact with a backside of the mounting board of the module, and a reservoir formed at the interconnection portion of the fluid conduit in a manner corresponding to the assistant heat dissipating pad, so as to allow heat exchange of the coolant fluid filled in the reservoir with the assistant heat dissipating pad, thereby further reducing the working temperature of the module.

7. The heat dissipating device according to claim 1, wherein the body is formed at its central portion with a through hole that communicates the upper surface with the lower surface, and wherein the through hole is adapted for receiving a protrusion block that protrudes from a back surface of the mounting board of the module opposite to amounting surface on which electrical devices are mounted.

8. A heat dissipating device adapted for use in combination with a module provided with a mounting board, the heat dissipating device comprising:
a metallic heat dissipating member disposed on a backside of the mounting board of the module, including a generally disc-shaped body, a plurality of heat dissipating fins, each having an upper end and a lower end, and a circular collecting pipe, wherein the body has a lower surface in contact with the backside of the mounting board of the module and is formed inside with a collecting annulus extending along the periphery thereof and has an upper surface formed with a pump unit installation recess, and wherein the heat dissipating fins extend upwardly from the upper surface of the body and radially arranged along the periphery of the body in a manner spaced apart from one another, each being formed with at least one channel that extends from the upper end to the lower end thereof and coupled in fluid communication with the collecting annulus, and wherein the circular collecting pipe is disposed at the upper ends of the heat dissipating fins and coupled in fluid communication with the channels of the heat dissipating fins;
a fan unit including a driving shaft, a set of fan blades and an active magnet, wherein the driving shaft has a lower end extending close to the body, and wherein the fan blades are mounted at an upper end of the driving shaft in such a manner that when the driving shaft is driven to rotate, the fan blades are rotated with the driving shaft, and wherein the active magnet is mounted at a lower end of the driving shaft in such a manner that the active magnet is rotatable with the driving shaft;
a pump unit including an accommodating case, a set of pump blades and a passive magnet, wherein the accommodating case is disposed in the pump unit installation recess of the body, so that the accommodating case has a top wall positioned close to the active magnet, and wherein the pump blades are arranged at a lower end of a mounting shaft extending downwardly from the top wall of the accommodating case, and wherein the passive magnet is disposed at an upper end of the mounting shaft at a position close to the top wall of the accommodating case and further connected to the pump blades, such that the passive magnet is rotatable with the pump blades;
an outlet conduit having an input end provided inside of the body and in fluid communication with a fluid output port of the accommodating case, and an output end extending upwardly and provided in fluid communication with the collecting pipe; and
an inlet conduit disposed within the body, having an output end in fluid communication with a fluid input port of the accommodating case and an input end in fluid communication with the collecting annulus.

9. The heat dissipating device according to claim 1, further comprising a plurality of assistant heat dissipating members attached to surfaces of the heat dissipating fins of the metallic heat dissipating member, each comprising:
a bottom layer, which is a flexible film having a first surface intimately attached to the surface of a corresponding heat dissipating fin and a second surface opposite to the first surface;
a first copper foil disposed on the second surface of the bottom layer, with both ends thereof extending beyond edges of the bottom layer in a manner contacting with the corresponding heat dissipating fin and the body of the metallic heat dissipating member, respectively;
an intermediate layer formed on the first copper foil, which is formed with a plurality of slots extending from one end to the other end of the intermediate layer and extending all the way through the thickness of the intermediate layer, wherein the intermediate layer is subjected to a sintering process, so that the respective slots are formed at walls thereof with a plurality of apertures;
a second copper foil disposed on the intermediate layer, with both ends thereof extending beyond edges of the intermediate layer in a manner contacting with the corresponding heat dissipating fin and the body of the metallic heat dissipating member, respectively; and
a top layer disposed on the second copper foil.

10. The heat dissipating device according to claim 5, further comprising a plurality of assistant heat dissipating members attached to surfaces of the heat dissipating fins of the metallic heat dissipating member, each comprising:
a bottom layer, which is a flexible film having a first surface intimately attached to the surface of a corresponding heat dissipating fin and a second surface opposite to the first surface;
a first copper foil disposed on the second surface of the bottom layer, with both ends thereof extending beyond edges of the bottom layer in a manner contacting with the corresponding heat dissipating fin and the body of the metallic heat dissipating member, respectively;
an intermediate layer formed on the first copper foil, which is formed with a plurality of slots extending from one end to the other end of the intermediate layer and extending all the way through the thickness of the intermediate layer, wherein the intermediate layer is subjected to a sintering process, so that the respective slots are formed at walls thereof with a plurality of apertures;
a second copper foil disposed on the intermediate layer, with both ends thereof extending beyond edges of the intermediate layer in a manner contacting with the corresponding heat dissipating fin and the body of the metallic heat dissipating member, respectively; and
a top layer disposed on the second copper foil.

11. The heat dissipating device according to claim 8, further comprising a plurality of assistant heat dissipating members attached to surfaces of the heat dissipating fins of the metallic heat dissipating member, each comprising:
a bottom layer, which is a flexible film having a first surface intimately attached to the surface of a corresponding heat dissipating fin and a second surface opposite to the first surface;
a first copper foil disposed on the second surface of the bottom layer, with both ends thereof extending beyond edges of the bottom layer in a manner contacting with the corresponding heat dissipating fin and the body of the metallic heat dissipating member, respectively;
an intermediate layer formed on the first copper foil, which is formed with a plurality of slots extending from one end to the other end of the intermediate layer and extending all the way through the thickness of the intermediate layer, wherein the intermediate layer is subjected to a sintering process, so that the respective slots are formed at walls thereof with a plurality of apertures;
a second copper foil disposed on the intermediate layer, with both ends thereof extending beyond edges of the intermediate layer in a manner contacting with the corresponding heat dissipating fin and the body of the metallic heat dissipating member, respectively; and
a top layer disposed on the second copper foil.

12. The heat dissipating device according to claim 9, wherein the bottom layer is made of a polyimide (PI) and a butadiene-styrene copolymer (BS), and wherein the apertures of the intermediate layer are filled with a fluid having a low combustion point, so that the fluid is rapidly gasified when the first and second copper foils perform heat exchange with t the body of the metallic heat dissipating member and the corresponding heat dissipating fin and the gasified low combustion point fluid will later return back to its liquid form in the apertures due to capillary condensation.

13. The heat dissipating device according to claim 10, wherein the bottom layer is made of a polyimide (PI) and a butadiene-styrene copolymer (BS), and wherein the apertures of the intermediate layer are filled with a fluid having a low combustion point, so that the fluid is rapidly gasified when the first and second copper foils perform heat exchange with t the body of the metallic heat dissipating member and the corresponding heat dissipating fin and the gasified low combustion point fluid will later return back to its liquid form in the apertures due to capillary condensation.

14. The heat dissipating device according to claim 11, wherein the bottom layer is made of a polyimide (PI) and a butadiene-styrene copolymer (BS), and wherein the apertures of the intermediate layer are filled with a fluid having a low combustion point, so that the fluid is rapidly gasified when the first and second copper foils perform heat exchange with t the body of the metallic heat dissipating member and the corresponding heat dissipating fin and the gasified low combustion point fluid will later return back to its liquid form in the apertures due to capillary condensation.

15. An apparatus comprising a heat dissipating device, the heat dissipating device comprising:
a thermally conductive unit including a mounting substrate, and a plurality of conductors disposed on the mounting substrate, wherein the mounting substrate has a first mounting surface and a second mounting surface which is opposite to the first mounting surface and overlaid with predetermined circuit traces, and wherein each of the conductors includes a first terminal electrically connected to the corresponding circuit traces provided on the second mounting surface of the mounting substrate and a second terminal adapted for being electrically connected to a module, so that when the respective conductors are provided with electric power, the second terminals have a lower temperature as compared to the first terminals, thereby reducing the working temperature of the light-emitting diodes; and
a fan unit mounted on the first mounting surface of the mounting substrate.

16. The apparatus according to claim 15, further comprising a light-emitting diode module, the module comprising:
a transparent mounting board;
a plurality of light-emitting diodes mounted on a mounting surface of the mounting board;
a plurality of lenses mounted on a back surface of the mounting board opposite to the mounting surface at positions corresponding to the light-emitting diodes; and
wherein the respective second terminals of the conductors are electrically connected to a corresponding one of the light-emitting diodes located in the module.

17. The light-emitting diode module according to claim 16, further comprising a reflective plate which surrounds the lenses.

18. The light-emitting diode module according to claim 16, wherein the respective lenses are configured to have a plurality of flat outer surfaces.

19. The apparatus according to claim 15, further comprising a solar cell module, the module comprising:
a transparent mounting board;
a transparent conductive layer mounted on a mounting surface of the mounting board;
a plurality of solar cells mounted on the mounting surface of the mounting board by means of the transparent conductive layer;
a plurality of lenses mounted on a back surface of the mounting board opposite to the mounting surface at positions corresponding to the solar cells; and
wherein the respective second terminals of the conductors are electrically connected to a corresponding one of the solar cells located in the module.

20. The solar cell module according to claim 19, further comprising a light converging lens that covers the transparent mounting board.

21. A heat dissipating device adapted for use in combination with a module provided with a mounting board, the heat dissipating device comprising:
a thermally conductive unit including an elongated thermally conductive plate having a first end and a second end, the mounting board of the module being adapted for being mounted on a surface of the first end of the thermally conductive plate, wherein the thermally conductive plate is adapted for transferring the heat generated by an element mounted on the mounting board of the module from the first end to the second end.

22. The heat dissipating device according to claim 21, further comprising a coolant fluid tank provided at the second end of the thermally conductive plate and filled with a coolant fluid.
